(19) United States
(12) Patent Application Publication
(10) Pub. No.: US 2025/0350264 A1
(43) Pub. Date: Nov. 13, 2025

(54) ACOUSTIC WAVE FILTER WITH WIDE PASS BAND

(71) Applicant: SKYWORKS SOLUTIONS, INC., Irvine, CA (US)

(72) Inventors: Rei Goto, Osaka-Shi (JP); Motoyuki Tajima, Yokohama-Shi (JP); Satoru Ikeuchi, Ashiya-Shi (JP); Yiliu Wang, Irvine, CA (US)

(21) Appl. No.: 19/199,597

(22) Filed: May 6, 2025

Related U.S. Application Data
(60) Provisional application No. 63/644,617, filed on May 9, 2024.

(51) Int. Cl. H03H 9/64; H03H 9/02; H03H 9/72

(52) U.S. Cl. CPC H03H 9/6483; H03H 9/02834; H03H 9/725

(57) ABSTRACT

Aspects and embodiments disclosed herein include an acoustic wave filter comprising a first and a second input/output port, a plurality of temperature compensated surface acoustic wave (TC-SAW) series resonators coupled in series between the first and the second input/output port and having a layer of piezoelectric material, an interdigital transducer (IDT) electrode arranged over the layer of piezoelectric material, and a temperature compensation layer formed over the IDT electrode, the plurality of TC-SAW series resonators including at least one first TC-SAW series resonator and at least one second TC-SAW series resonator, a thickness of the temperature compensation layer of the at least one first TC-SAW series resonator being less than that of the at least one second TC-SAW series resonator, a plurality of TC-SAW shunt resonators coupling the plurality of TC-SAW series resonators to ground, and an inductor connected in parallel to the at least one first TC-SAW series resonator.

### CROSS-REFERENCE TO RELATED APPLICATIONS

This application claims priority under 35 U.S.C. § 119(e) to U.S. Provisional Patent Application Ser. No. 63/644,617, titled “ACOUSTIC WAVE FILTER WITH WIDE PASS BAND,” filed May 9, 2024, the entire content of which is incorporated herein by reference for all purposes.

### BACKGROUND

### Field

Aspects and embodiments disclosed herein relate to acoustic wave filters, and in particular, to band pass filters with temperature compensated surface acoustic wave resonators.

### Description of Related Technology

An acoustic wave filter can include a plurality of resonators arranged to filter radio frequency (RF) signals. Examples of acoustic wave resonators include surface acoustic wave (SAW) resonators and bulk acoustic wave (BAW) resonators. A surface acoustic wave resonator can include an interdigital transductor electrode on a layer of piezoelectric material. The surface acoustic wave resonator can generate a surface acoustic wave on a surface of the layer of piezoelectric material on which the interdigital transductor electrode is disposed. In BAW resonators, acoustic waves propagate in a bulk of a layer of piezoelectric material. Example BAW resonators include film bulk acoustic wave resonators and solidly mounted resonators (SMRs).

Acoustic wave filters can be implemented in RF electronic systems. For instance, filters in a radio frequency front end (RFFE) of an RF communication system can include acoustic wave filters. Examples of RF communication systems include, but are not limited to, mobile phones, tablets, base stations, network access points, customer-premises equipment (CPE), laptops, and wearable electronics. An acoustic wave filter can be a band pass filter. A plurality of acoustic wave filters can be arranged as a multiplexer. For example, two acoustic wave filters can be arranged as a duplexer. In some implementations, acoustic wave filters with a relatively wide passband can be desirable.

### SUMMARY

In certain embodiments, the present disclosure relates to an acoustic wave filter. The acoustic wave filter includes a first input/output port and a second input/output port. The acoustic wave filter further includes a plurality of temperature compensated surface acoustic wave (TC-SAW) series resonators. Each of the plurality of TC-SAW series resonators has a layer of piezoelectric material, an interdigital transducer (IDT) electrode arranged over the layer of piezoelectric material, and a temperature compensation layer formed over the IDT electrode. The plurality of TC-SAW series resonators are coupled in series between the first input/output port and the second input/output port. The plurality of TC-SAW series resonators include at least one first TC-SAW series resonator and at least one second TC-SAW series resonator. A thickness of the temperature compensation layer of the at least one first TC-SAW series resonator is less than a thickness of the temperature compensation layer of the at least one second TC-SAW series resonator of the plurality of TC-SAW series resonators. The acoustic wave filter further includes a plurality of TC-SAW shunt resonators coupling the plurality of TC-SAW series resonators to ground, and an inductor connected in parallel to the at least one first TC-SAW series resonator.

In various embodiments, the temperature compensation layers of the plurality of TC-SAW series resonators are silicon dioxide (SiO₂) layers. According to several embodiments, the IDT electrodes of the plurality of TC-SAW series resonators include a bus bar and IDT fingers extending from the bus bar, the IDT fingers having a pitch of λ corresponding to a wavelength of a resonant frequency of the plurality of TC-SAW series resonators. In some embodiments, the thickness of the temperature compensation layer of the at least one first TC-SAW series resonator has a value between about 0.2 λ and about 0.4 λ. In a number of embodiments, the thickness of the temperature compensation layer of the at least one second TC-SAW series resonator has a value of larger than about 0.5 λ.

In some embodiments, the layer of piezoelectric material is a lithium tantalate or lithium niobate layer. According to a number of embodiments, the layer of piezoelectric material of the plurality of TC-SAW series resonators includes a lithium niobate crystal with a 120° to 132° rotated Y-cut, X-propagating cut angle (120°-132° YX-LN). 120°-132° YX-LN can be expressed in Euler angles (φ, θ, ψ) as −15°<φ<+15°, 90°+120<θ<90°+132°, and −15°<ψ<+15°.

In several embodiments, the acoustic wave filter is a ladder-type acoustic wave filter. According to a number of embodiments, the acoustic wave filter is a lattice-type or a hybrid ladder-lattice-type acoustic wave filter. In some embodiments, the acoustic wave filter is a band pass filter.

In various embodiments, the plurality of TC-SAW shunt resonators include at least one first TC-SAW shunt resonator and at least one second TC-SAW shunt resonator, a thickness of a temperature compensation layer of the at least one first TC-SAW shunt resonator being less than a thickness of a temperature compensation layer of the at least one second TC-SAW shunt resonator.

In some embodiments, the acoustic wave filter is a band pass filter.

In some embodiments, the first input/output port is a transmit port for a transmit filter or a receive port for a receive filter, and the second input/output port is an antenna port configured to be connected to an antenna.

In a few embodiments, the at least one first TC-SAW series resonator and the inductor connected in parallel to the at least one first TC-SAW series resonator are directly coupled to the first input/output port. According to a number of embodiments, the at least one first TC-SAW series resonator and the inductor connected in parallel to the at least one first TC-SAW series resonator are directly coupled to the second input/output port.

In certain other embodiments, the present disclosure relates to a radio-frequency (RF) module. In some implementations, the RF module may be a RF front-end (RFFE) module. The RF module includes an acoustic wave filter. The acoustic wave filter includes a first input/output port and a second input/output port. The acoustic wave filter further includes a plurality of temperature compensated surface acoustic wave (TC-SAW) series resonators. Each of the TC-SAW series resonators has a layer of piezoelectric material, an interdigital transducer (IDT) electrode arranged over the layer of piezoelectric material, and a temperature compensation layer formed over the IDT electrode. The plurality of TC-SAW series resonators are coupled in series between the first input/output port and the second input/output port. The plurality of TC-SAW series resonators include at least one first TC-SAW series resonator and at least one second TC-SAW series resonator. A thickness of the temperature compensation layer of the at least one first TC-SAW series resonator is less than a thickness of the temperature compensation layer of the at least one second TC-SAW series resonator. The acoustic wave filter further includes a plurality of TC-SAW shunt resonators coupling the plurality of TC-SAW series resonators to ground, and an inductor connected in parallel to the at least one first TC-SAW series resonator. The RF module further includes an RF antenna coupled to the second input/output port, and a power amplifier coupled to the first input/output port and configured to amplify an RF signal for transmission or received by the RF antenna.

In a number of embodiments, the temperature compensation layers of the plurality of TC-SAW series resonators are silicon dioxide (SiO₂) layers. According to some embodiments, the IDT electrodes of the plurality of TC-SAW series resonators include a bus bar and IDT fingers extending from the bus bar, the IDT fingers having a pitch of λ corresponding to a wavelength of a resonant frequency of the plurality of TC-SAW series resonators. In a few embodiments, the thickness of the temperature compensation layer of the at least one first TC-SAW series resonator has a value between about 0.2 λ and about 0.4 λ. According to various of embodiments, the thickness of the temperature compensation layer of the at least one second TC-SAW series resonator has a value of larger than about 0.5 λ.

In several embodiments, the piezoelectric material layer is a lithium tantalate or lithium niobate layer. In some embodiments, the piezoelectric material layer of the plurality of TC-SAW series resonators includes a lithium niobate crystal with a 120° to 132° rotated Y-cut, X-propagating cut angle (120°-132° YX-LN). 120°-132° YX-LN can be expressed in Euler angles (φ, θ, ψ) as −15°<φ<+15°, 90°+120<θ<90°+132°, and −15°<ψ<+15°.

According to a number of embodiments, the acoustic wave filter is a ladder-type acoustic wave filter. According to various embodiments, the acoustic wave filter is a lattice-type or a hybrid ladder-lattice-type acoustic wave filter. In a few embodiments, the acoustic wave filter is a band pass filter.

In some embodiments, the plurality of TC-SAW shunt resonators include at least one first TC-SAW shunt resonator and at least one second TC-SAW shunt resonator, a thickness of a temperature compensation layer of the at least one first TC-SAW shunt resonator being less than a thickness of a temperature compensation layer of the at least one second TC-SAW shunt resonator.

In some embodiments, the acoustic wave filter is a band pass filter.

In some embodiments, the acoustic wave filter is a transmit filter or a receive filter, and the second input/output port is an antenna port connected to the RF antenna.

In various embodiments, the first input/output port is a transmit port for a transmit filter or a receive port for a receive filter, and the second input/output port is an antenna port configured to be connected to an antenna.

In a number of embodiments, the at least one first TC-SAW series resonator and an inductor connected in parallel to the at least one first TC-SAW series resonator are directly coupled to the first input/output port. According to some embodiments, the at least one first TC-SAW series resonator and the inductor connected in parallel to the at least one first TC-SAW series resonator are directly coupled to the second input/output port.

In certain other embodiments, the present disclosure relates to a multiplexer. The multiplexer includes a first input/output port, a second input/output port and a third input/output port. The multiplexer further includes a first plurality of temperature compensated surface acoustic wave (TC-SAW) series resonators coupled in series between the first input/output port and the second input/output port. Each of the first plurality of TC-SAW series resonators has a layer of piezoelectric material, an interdigital transducer (IDT) electrode arranged over the layer of piezoelectric material, and a temperature compensation layer formed over the IDT electrode. The first plurality of TC-SAW series resonators include at least one first TC-SAW series resonator and at least one second TC-SAW series resonator. A thickness of the temperature compensation layer of the at least one first TC-SAW series resonator is less than a thickness of the temperature compensation layer of the at least one second TC-SAW series resonator. The multiplexer further includes a second plurality of TC-SAW series resonators coupled in series between the second input/output port and the third input/output port. Each of the second plurality of TC-SAW series resonators has a layer of piezoelectric material, an IDT electrode arranged over the layer of piezoelectric material, and a temperature compensation layer formed over the IDT electrode. The second plurality of TC-SAW series resonators include at least one third TC-SAW series resonator and at least one fourth TC-SAW series resonator. A thickness of the temperature compensation layer of the at least one third TC-SAW series resonator is less than a thickness of the temperature compensation layer of the at least one fourth TC-SAW series resonator. The multiplexer further includes a plurality of TC-SAW shunt resonators coupling the first plurality of TC-SAW series resonators and the second plurality of TC-SAW series resonators to ground. The multiplexer further includes a first inductor connected in parallel to the at least one first TC-SAW series resonator, and a second inductor connected in parallel to the at least one third TC-SAW series resonator.

In certain other embodiments, the present disclosure relates to a wireless communication device. In some implementations, the wireless communication device may be a mobile phone, particularly for 5G communication. The wireless communication device includes an acoustic wave filter. The acoustic wave filter includes a first input/output port and a second input/output port. The acoustic wave filter further includes a plurality of temperature compensated surface acoustic wave (TC-SAW) series resonators. Each of the TC-SAW series resonators has a layer of piezoelectric material, an interdigital transducer (IDT) electrode arranged over the layer of piezoelectric material, and a temperature compensation layer formed over the IDT electrode. The plurality of TC-SAW series resonators are coupled in series between the first input/output port and the second input/output port. The plurality of TC-SAW series resonators include at least one first TC-SAW series resonator and at least one second TC-SAW series resonator. A thickness of the temperature compensation layer of the at least one first TC-SAW series resonator is less than a thickness of the temperature compensation layer of the at least one second TC-SAW series resonator. The acoustic wave filter further includes a plurality of TC-SAW shunt resonators coupling the plurality of TC-SAW series resonators to ground, and an inductor connected in parallel to the at least one first TC-SAW series resonator. The wireless communication device further includes an antenna operatively coupled to the second input/output port of the acoustic wave filter, a radio frequency (RF) amplifier operatively coupled to the first input/output port acoustic wave filter and configured to amplify an RF signal, and a transceiver in communication with the RF amplifier.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will now be described, by way of non-limiting example, with reference to the accompanying drawings.

FIG. 1A is a cross-sectional view of a temperature compensated surface acoustic wave (TC-SAW) device having a temperature compensation layer of a first thickness.

FIG. 1B is a top view of the TC-SAW device of FIG. 1A.

FIG. 2A is a cross-sectional view of a TC-SAW device having a temperature compensation layer of a second thickness.

FIG. 2B is a top view of the TC-SAW device of FIG. 2A.

FIG. 3 is a schematic diagram of an acoustic wave filter in ladder topology according to an embodiment.

FIG. 4 is a schematic diagram of two acoustic wave filters in ladder topology forming a duplexer according to another embodiment.

FIG. 5 is a schematic diagram of two acoustic wave filters in ladder topology forming a multiplexer according to another embodiment.

FIG. 6 is a graph comparing insertion loss of the ladder filter of FIG. 3 to a conventional acoustic wave filter in a passband of the filters.

FIG. 7 is a graph comparing insertion loss of the ladder filter of FIG. 3 to a conventional acoustic wave filter over a wider frequency range than in FIG. 6.

FIG. 8 is a schematic diagram of a generalized acoustic wave filter in ladder topology according to another embodiment.

FIG. 9 is a cross-sectional view of a bulk acoustic wave (BAW) device.

FIG. 10 is a cross-sectional view of a Lamb wave resonator.

FIG. 11 is a schematic diagram of an acoustic wave filter in lattice topology.

FIG. 12 is a schematic diagram of an acoustic wave filter in hybrid ladder-and-lattice topology.

FIG. 13 is a schematic block diagram of an illustrative packaged module according to an embodiment.

FIG. 14 is a schematic diagram of one embodiment of a mobile device.

FIG. 15 is a schematic diagram of one example of a communication network.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings in which like reference numerals can indicate identical or functionally similar elements.

It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

As the demand for processing wideband radio frequency signals increases, band pass filters with a wide passband are desired. For example, for filtering a radio frequency signal in a fifth generation (5G) New Radio (NR) operating band within Frequency Range 1 (FR1) or Frequency Range 2 (FR2), a wide passband of a band pass filter can be useful in some implementations.

A multiplexer, such as a duplexer, in accordance with any suitable principles and advantages disclosed herein, can include one or more acoustic wave filters arranged to filter a radio frequency signal in a 5G NR operating band within FR1. FR1 can be from 410 megahertz (MHz) to 7.125 gigahertz (GHz), for example, as specified in a current 5G NR specification. An acoustic wave filter of any of the embodiments disclosed herein can be arranged to filter a radio frequency signal in a fourth generation (4G) Long Term Evolution (LTE) operating band. An acoustic wave filter of any of the embodiments disclosed herein can have a passband that includes a 4G LTE operating band and a 5G NR operating band.

Developing band pass filters with a wide passband can be challenging. For example, two filters can be connected in parallel with each other to implement a wideband filter. The two filters can be designed to have the same impedance (e.g., 50 Ohms), and these impedances can be matched throughout the entire passband. However, this can result in one of the two filters with a lower frequency passband having a relatively large capacitance. Impedance matching elements may cause packaging constraints for the filter components and other components included in the same module as the filter components.

Other possibilities may include connecting inductive circuit elements in parallel and/or in series to acoustic wave resonator stages or varying the material of the layer of piezoelectric material of the acoustic wave resonators to increase the effective electromechanical coupling coefficient or coupling factor (K²), i.e., the effectiveness with which the acoustic wave resonator converts stored mechanical energy into electrical energy.

Embodiments of this disclosure relate to a band pass filter that includes temperature compensated surface acoustic wave (TC-SAW) resonators having temperature compensation layers of different thickness. A TC-SAW resonator with a temperature compensation layer of comparably low thickness is connected in parallel to an inductor in a first series resonator stage. The first series resonator stage is coupled to a second series resonator stage formed by a TC-SAW resonator with a temperature compensation layer of comparably high thickness. Such a combination of a TC-SAW resonator having a temperature compensation layer of comparably low thickness with an inductive circuit element connected in parallel thereto widens the passband of a band pass filter in comparison to an acoustic wave filter employing only TC-SAW resonators having temperature compensation layers of similar thickness.

Example TC-SAW resonators will now be discussed.

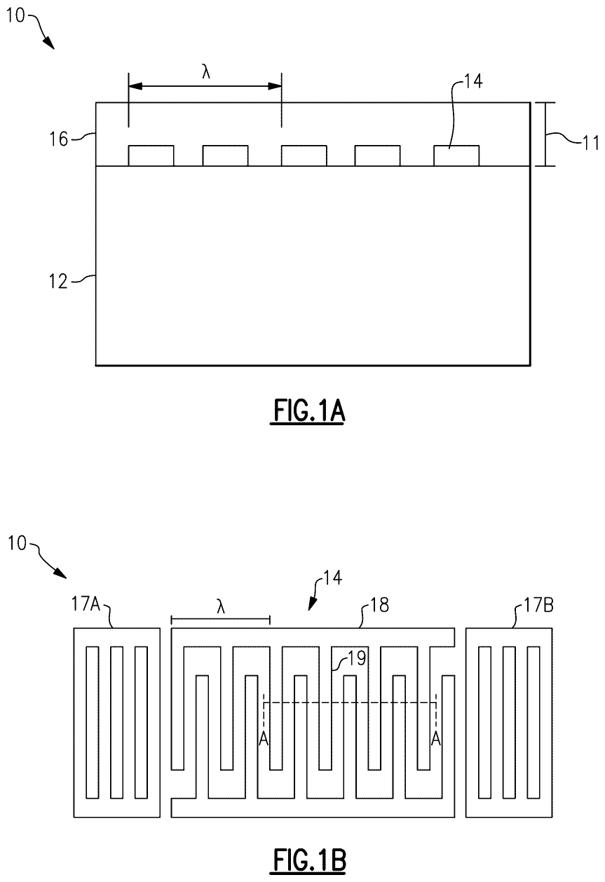

FIG. 1A is a cross sectional view of a TC-SAW device 10. The TC-SAW device 10 can be a TC-SAW resonator. As illustrated, the TC-SAW device 10 includes a layer of piezoelectric material 12, an interdigital transducer (IDT) electrode 14, and a temperature compensation layer 16 over the IDT electrode 14.

The layer of piezoelectric material 12 can be a lithium based layer of piezoelectric material. For example, the layer of piezoelectric material 12 can be a lithium niobate (LiNbO₃) layer. As another example, the layer of piezoelectric material 12 can be a lithium tantalate (LiTaO₃) layer. The layer of piezoelectric material 12 may, for example, include a lithium niobate crystal with a 120° to 132° rotated Y-cut, X-propagating cut angle (120°-132° YX-LN). 120°-132° YX-LN can be expressed in Euler angles (φ, θ, ψ) as −15°<φ<+15°, 90°+120<θ<90°+132°, and −15°<ψ<+15°.

In the TC-SAW device 10, the IDT electrode 14 is arranged over the layer of piezoelectric material 12. As illustrated, the IDT electrode 14 has a first side in physical contact with the layer of piezoelectric material 12 and a second side in physical contact with the temperature compensation layer 16. The IDT electrode 14 can include aluminum (Al), molybdenum (Mo), tungsten (W), gold (Au), silver (Ag), copper (Cu), platinum (Pt), ruthenium (Ru), titanium (Ti), the like, or any suitable combination or alloy thereof. The IDT electrode 14 can be a multi-layer IDT electrode in some implementations.

In the TC-SAW device 10, the temperature compensation layer 16 can bring a temperature coefficient of frequency (TCF) of the TC-SAW device 10 closer to zero. The temperature compensation layer 16 can have a positive TCF. This can compensate for a negative TCF of the layer of piezoelectric material 12. The layer of piezoelectric material 12 can be lithium niobate or lithium tantalate, which both have a negative TCF. The temperature compensation layer 16 can be a dielectric film. The temperature compensation layer 16 can be a silicon dioxide (SiO₂) layer having a first thickness 11, i.e., an extension perpendicular to the plane of the layer of piezoelectric material 12. In some other embodiments, a different temperature compensation layer 16 can be implemented. Some examples of other temperature compensation layers include a tellurium dioxide (TeO₂) layer or a silicon oxyfluoride (SiOF) layer.

FIG. 1B illustrates the IDT electrode 14 of the TC-SAW device 10 of FIG. 1A in plan view. The view of the TC-SAW device 10 in FIG. 1A is along the dashed line from A to A in FIG. 1B. The temperature compensation layer 16 is not shown in FIG. 1B to focus on the IDT electrode 14. The IDT electrode 14 is positioned between a first acoustic reflector 17A and a second acoustic reflector 17B. The acoustic reflectors 17A and 17B are separated from the IDT electrode 14 by respective gaps. The IDT electrode 14 includes a bus bar 18 and IDT fingers 19 extending from the bus bar 18. The IDT fingers 19 have a pitch of λ. The TC-SAW device 10 can include any suitable number of IDT fingers 19. The pitch λ of the IDT fingers 19 corresponds to the wavelength of a resonant frequency of the TC-SAW device 10.

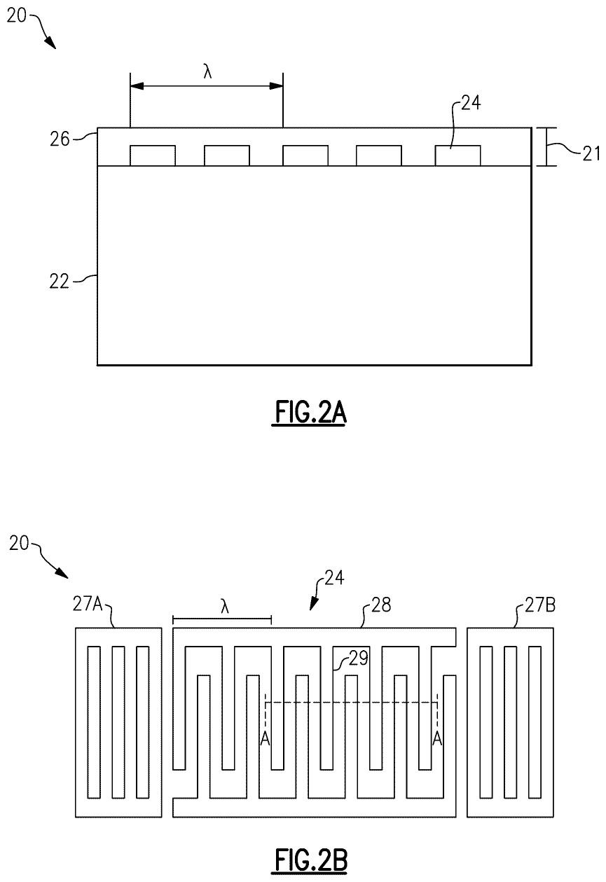

FIG. 2A is a cross-sectional view of another TC-SAW device 20. The TC-SAW device 20 can be a TC-SAW resonator. As illustrated, and similar to the TC-SAW device 10 of FIG. 1A and 1B, the TC-SAW device 20 includes a layer of piezoelectric material 22, an interdigital transducer (IDT) electrode 24, and a temperature compensation layer 26 over the IDT electrode 24. FIG. 2B illustrates the IDT electrode 24 of the TC-SAW device 20 of FIG. 2A in plan view. Again, the view of the TC-SAW device 20 in FIG. 2A is along the dashed line from A to A in FIG. 2B.

The TC-SAW device 20 is similar to the TC-SAW device 10 of FIG. 1A and 1B, except that the temperature compensation layer 26 has a second thickness 21, i.e., an extension perpendicular to the plane of the layer of piezoelectric material 22, which is less compared to the first thickness 11 of the TC-SAW device 10 of FIG. 1A and 1B. For example, the second thickness 21 may have a value between about 0.2 λ and about 0.4 λ. In contrast thereto, the first thickness may have a value of larger than about 0.5 λ. The thicknesses of the temperature compensation layers 16 and 26 may be achieved by suitable process control during manufacture of the TC-SAW devices 10 and 20, respectively.

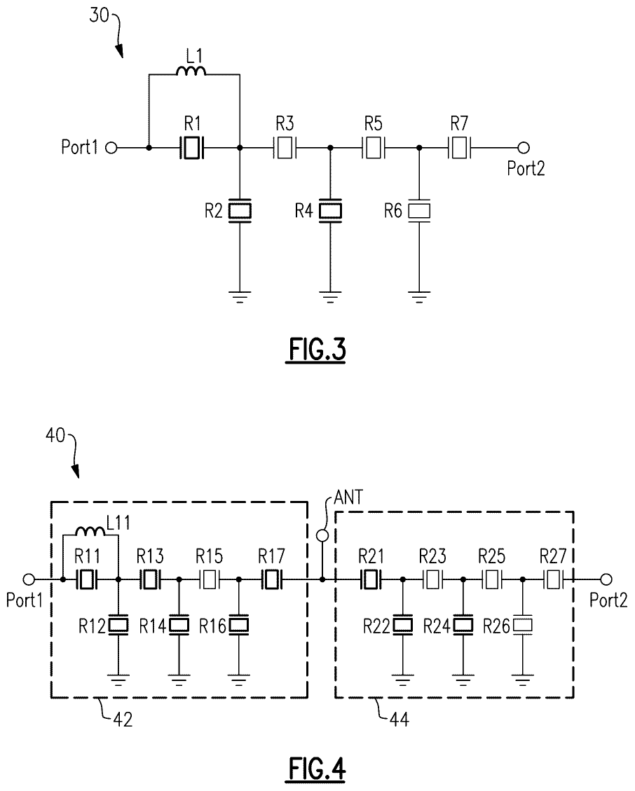

FIG. 3 is a schematic diagram of a ladder filter 30 according to an embodiment. The ladder filter 30 includes shunt resonators R2, R4, and R6 and series resonators R1, R3, R5, and R7 coupled between a first RF input/output port Port1 and a second RF input/output port Port2. The ladder filter 30 is an example topology of a band pass filter formed from acoustic wave resonators. In a band pass filter with a ladder filter topology, the shunt resonators can have lower resonant frequencies than the series resonators. The ladder filter 30 can be arranged to filter an RF signal input to either of the RF input/output ports Port1 and Port2 and output at the other RF input/output port Port2 or Port1. The first RF input/output port Port1 can be a transmit port for a transmit filter or a receive port for a receive filter. The second RF input/output port Port2 can be an antenna port. Any suitable number of series acoustic wave resonators can be included in a ladder filter. Any suitable number of shunt acoustic wave resonators can be included in a ladder filter.

As illustrated, the shunt resonators R2 and R4 include TC-SAW resonators 20 having a temperature compensation layer 26 of comparably low thickness 21, while the shunt resonator R6 includes a TC-SAW resonator 10 having a temperature compensation layer 16 of comparably high thickness 11. The illustrated series resonators R3, R5, and R7 closer to the second RF input/output port Port2 include TC-SAW resonators 10 having a temperature compensation layer 16 of comparably high thickness 11 as well. In the figures, the TC-SAW resonators having a temperature compensation layer 26 of comparably low thickness 21 are shown in bold, while the TC-SAW resonators 10 having a temperature compensation layer 16 of comparably high thickness 11 are not bolded.

The illustrated series resonator R1 closer to the first RF input/output port Port1 includes a TC-SAW resonator 20 having a temperature compensation layer 26 of comparably low thickness 21. Moreover, an inductor L1 is connected in parallel to the series resonator R1.

FIG. 4 is a schematic diagram of two acoustic wave filters 42 and 44 in ladder topology forming a duplexer 40 according to another embodiment. The first acoustic wave filter 42 includes shunt resonators R12, R14, and R16 and series resonators R11, R13, R15, and R17 coupled between a first RF input/output port Port1 and an antenna port ANT. The second acoustic wave filter 44 includes shunt resonators R22, R24, and R26 and series resonators R21, R23, R25, and R27 coupled between a second RF input/output port Port2 and the antenna port ANT. The duplexer 40 is an example topology of a band pass filter formed from acoustic wave resonators. In a band pass filter with a ladder filter topology, the shunt resonators can have lower resonant frequencies than the series resonators. The first acoustic wave filter 42 can be a transmission filter arranged to filter an RF signal input to the first RF input/output port Port1 and output at the antenna port ANT for transmission by an antenna. The second acoustic wave filter 44 can be a receive filter arranged to filter an RF signal received by an antenna, input at the antenna port ANT and output to the second RF input/output port Port2 for processing by an RF front-end module. Any suitable number of series acoustic wave resonators can be included in a duplexer. Any suitable number of shunt acoustic wave resonators can be included in a duplexer.

As illustrated, the shunt resonators R12, R14, and R16 of the first acoustic wave filter 42 include TC-SAW resonators 20 having a temperature compensation layer 26 of comparably low thickness 21. The shunt resonators R22 and R24 of the second acoustic wave filter 44 include TC-SAW resonators 20 having a temperature compensation layer 26 of comparably low thickness 21 as well, while the shunt resonator R26 of the second acoustic wave filter 44 includes a TC-SAW resonator 10 having a temperature compensation layer 16 of comparably high thickness 11. The illustrated series resonator R15 of the first acoustic wave filter 42 and the illustrated series resonators R23, R25, and R27 of the second acoustic wave filter 44 include TC-SAW resonators 10 having a temperature compensation layer 16 of comparably high thickness 11 as well. In contrast thereto, the illustrated series resonators R11, R13, and R17 of the first acoustic wave filter 42 and the illustrated series resonator R21 of the second acoustic wave filter 44 include TC-SAW resonators 20 having a temperature compensation layer 26 of comparably low thickness 21. Moreover, an inductor L11 is connected in parallel to the series resonator R11 of the first acoustic wave filter 42.

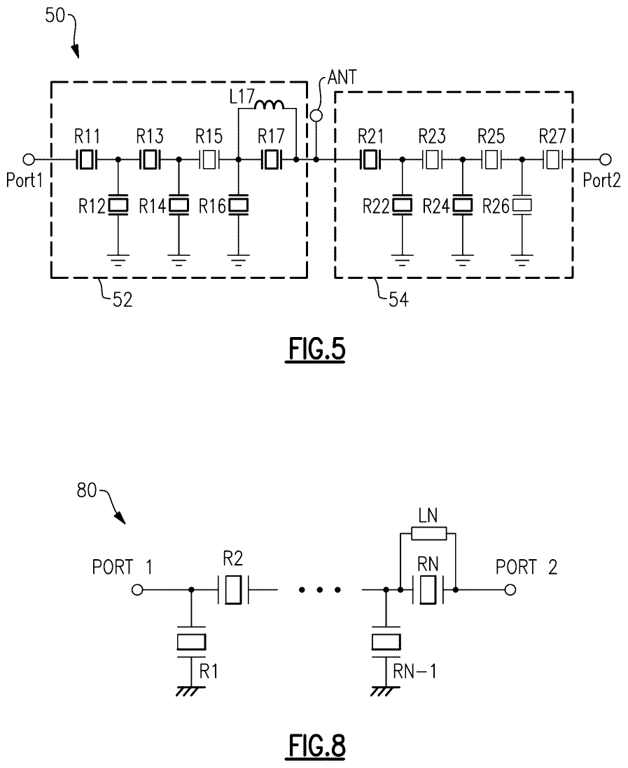

FIG. 5 is a schematic diagram of two acoustic wave filters 52 and 54 in ladder topology forming a multiplexer 50 according to another embodiment. The multiplexer 50 is implemented similar to the duplexer 40 of FIG. 4, except that an inductor L17 is not connected in parallel to the series resonator R11 of the first acoustic wave filter 42, but in parallel to the series resonator R17 of the first acoustic wave filter 42. Due to the arrangement of the parallel combination of the series resonator R17 and inductor L17 closer to the antenna port ANT, the multiplexer 50 is more resilient to higher loads than the duplexer 40.

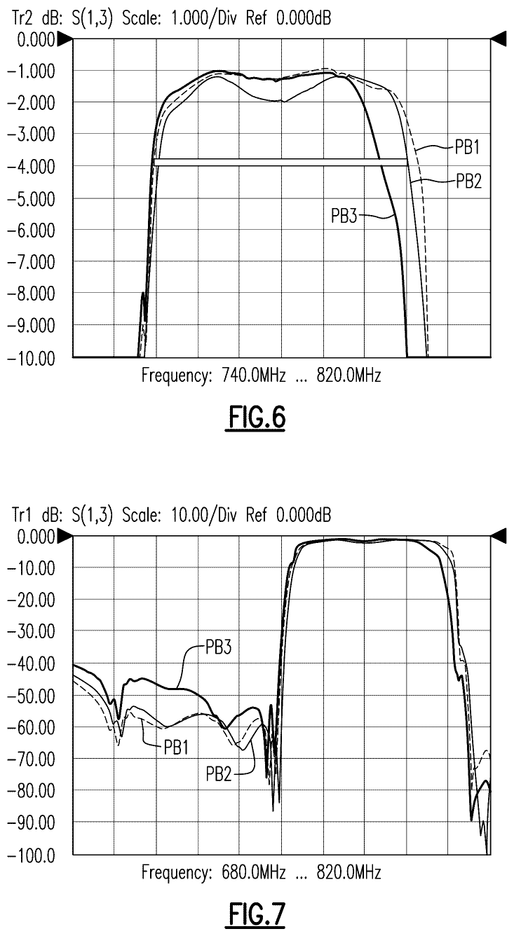

FIG. 6 is a graph comparing insertion loss of the ladder filter 30 of FIG. 3 to a conventional acoustic wave filter in a passband of the filters. FIG. 7 is a graph comparing insertion loss of the ladder filter 30 of FIG. 3 to the same conventional acoustic wave filter over a wider frequency range than in FIG. 6. As can be seen from FIG. 6, the passband of the ladder filter 30 (outermost curve PB1) is considerably wider than the passband of a conventional acoustic wave filter having TC-SAW resonators all having the same thickness of the temperature compensation layer (innermost curve PB3). Additionally, the passband of the ladder filter 30 (outermost curve PB1) is also wider than the passband of a conventional acoustic wave filter having an inductor connected in parallel to one of the series TC-SAW resonators, but with the TC-SAW resonators still all having the same thickness of the temperature compensation layer (middle curve PB2).

FIG. 8 is a schematic diagram of a generalized acoustic wave filter 80 in ladder topology according to another embodiment. The ladder filter 80 includes a plurality of acoustic wave resonators R1, R2, . . . , RN−1, and RN arranged between a first input/output port PORT 1 and a second input/output port PORT 2. One of the input/output ports PORT 1 or PORT 2 can be an antenna port. In certain instances, the other of the input/output ports PORT 1 or PORT 2 can be a receive port. In some other instances, the other of the input/output ports PORT 1 or PORT 2 can be a transmit port.

The ladder filter 80 illustrates that any suitable number of ladder stages can be implemented in a ladder filter in accordance with any suitable principles and advantages disclosed herein. Ladder stages can start with a series resonator or a shunt resonator from any input/output port of the ladder filter 80 as suitable. As illustrated, the first ladder stage from the input/output port PORT 1 begins with a shunt resonator R1. As also illustrated, the first ladder stage from the input/output port PORT 2 begins with a series resonator RN. Moreover, the series resonator RN is connected in parallel to an inductor LN. Some of the series resonators can be TC-SAW resonators with a temperature compensation layer of comparably high thickness, while some others of the series resonators can be TC-SAW resonators with a temperature compensation layer of comparably low thickness. Similarly, some of the shunt resonators can be TC-SAW resonators with a temperature compensation layer of comparably high thickness, while some others of the shunt resonators can be TC-SAW resonators with a temperature compensation layer of comparably low thickness. The series resonators connected in parallel to an inductor, such as, for example, the series resonator RN, are TC-SAW resonators with a temperature compensation layer of comparably low thickness.

In some implementations of an acoustic wave filter that includes TC-SAW series resonators and TC-SAW shunt resonators having temperature compensation layers of different thicknesses, one or more series resonators close to a transmit port (or the lower frequency series resonators) can be BAW resonators to help with ruggedness. An example for such an implementation may be a transmit filter with a relatively high power handling specification.

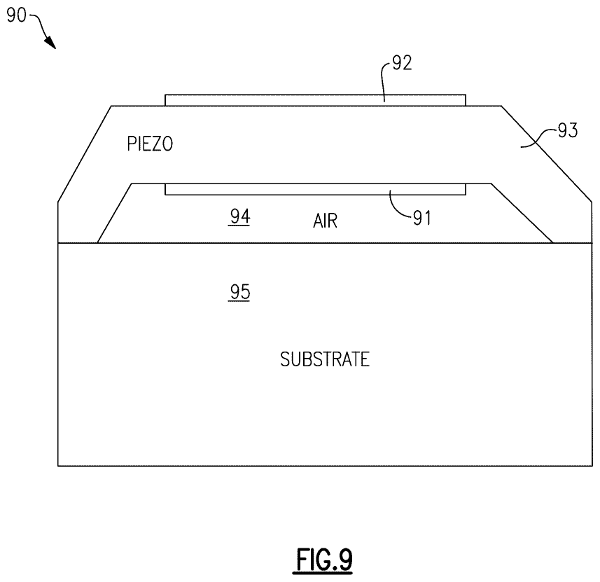

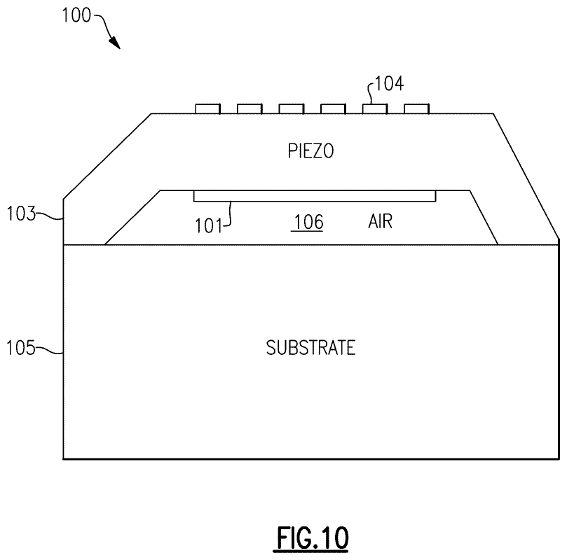

FIG. 9 is a cross sectional view of a bulk acoustic wave (BAW) device 90. The BAW device 90 can be a BAW resonator as used, for example, in an acoustic wave filter according to some of the embodiments disclosed herein. The illustrated BAW device 90 is a film bulk acoustic wave resonator. The BAW device 90 includes a first electrode 91, a second electrode 92, a layer of piezoelectric material 93, an air cavity 94, and a substrate 95. The electrodes 91 and 92 are on opposing sides of the layer of piezoelectric material 93. The layer of piezoelectric material 93 can be a thin film. The layer of piezoelectric material 93 can be an aluminum nitride layer, for example. In other instances, the layer of piezoelectric material 93 can be any other suitable layer of piezoelectric material. The air cavity 94 is disposed between the electrode 91 and the substrate 95. The substrate 95 can be a semiconductor substrate. For example, the substrate 95 can be a silicon substrate. The substrate 95 can be any other suitable substrate, such as a quartz substrate, a sapphire substrate, a spinel substrate, a ceramic substrate, a glass substrate, or the like. Although not shown in FIG. 9, the BAW device 90 can include a raised frame structure and/or a recessed frame structure.

The ladder filter 80 of FIG. 8 can include a third type of resonator as a shunt resonator and/or as a series resonator. The third type of resonator can be a Lamb wave resonator, for example. One such example Lamb wave resonator will be discussed with reference to FIG. 10. The acoustic wave filter 80 can include—in addition to the TC-SAW resonators having temperature compensation layers of different thicknesses as explained above—some shunt resonators including Lamb wave resonators. The acoustic wave filter 80 can further include some series resonators including Lamb wave resonators and some shunt resonators including BAW resonators.

FIG. 10 is a cross-sectional diagram of a Lamb wave resonator 100. A Lamb wave resonator can implement one or more series resonators and/or one or more shunt resonators in the ladder filter 80. The Lamb wave resonator 100 includes features of a SAW resonator and a film bulk acoustic wave resonator. As illustrated, the Lamb wave resonator 100 includes a layer of piezoelectric material 103, an IDT electrode 104 on the layer of piezoelectric material 103, and an electrode 101. The resonant frequency of the Lamb wave resonator 100 can be based on the thickness of the layer of piezoelectric material 103 and/or the geometry of the IDT electrode 104. An air cavity 106 is disposed between the electrode 101 and a substrate 105. Although the Lamb wave resonator 100 of FIG. 10 is a free standing Lamb wave resonator, a solidly mounted resonator (SMR) Lamb wave resonator with a solid acoustic mirror (e.g., acoustic Bragg reflectors) can alternatively or additionally be implemented.

An acoustic wave filter including TC-SAW resonators having temperature compensation layers of different thicknesses and an inductor connected in parallel to a series TC-SAW resonator having a temperature compensation layer of comparably low thicknesses in accordance with any suitable principles and advantages disclosed herein can be implemented in a variety of different filter topologies. Example filter topologies include, without limitation, ladder filters, lattice filters, hybrid ladder and lattice filters, filters that include ladder stages and a multi-mode SAW filter, and the like. Some example filter topologies will now be discussed.

FIG. 11 is a schematic diagram of a lattice filter 110. The lattice filter 110 is an example topology of a band pass filter formed from acoustic wave resonators. The lattice filter 110 can be arranged to filter an RF signal. As illustrated, the lattice filter 110 includes acoustic wave resonators RL1, RL2, RL3, and RL4. The acoustic wave resonators RL1 and RL2 are series resonators. An inductor LL1 is connected in parallel to the acoustic wave resonator RL1. The acoustic wave resonators RL3 and RL4 are shunt resonators. The illustrated lattice filter 110 has a balanced input and a balanced output. The lattice filter 110 can be implemented with different types of acoustic wave resonators in accordance with any suitable principles and advantages disclosed herein. For example, the series resonator RL1 can include a TC-SAW resonator 20 with a temperature compensation layer 26 of comparably low thickness 21, while the series resonator RL2 can include a TC-SAW resonator 10 with a temperature compensation layer 16 of comparably high thickness 11. Similarly, the shunt resonator RL3 can include a TC-SAW resonator 20 with a temperature compensation layer 26 of comparably low thickness 21, while the shunt resonator RL4 can include a TC-SAW resonator 10 with a temperature compensation layer 16 of comparably high thickness 11.

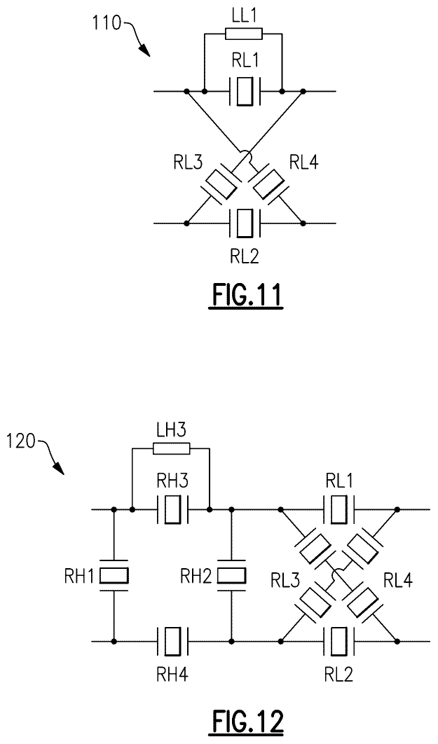

FIG. 12 is a schematic diagram of a hybrid ladder and lattice filter 120. The illustrated hybrid ladder and lattice filter 120 includes series acoustic wave resonators RL1, RL2, RH3, and RH4, shunt acoustic wave resonators RL3, RL4, RH1, and RH2, and an inductor LH3 connected in parallel to the series acoustic wave resonator RH3. The hybrid ladder and lattice filter 120 can be implemented with different types of acoustic wave resonators in accordance with any suitable principles and advantages disclosed herein. For example, the series resonator RH3 can include a TC-SAW resonator 20 with a temperature compensation layer 26 of comparably low thickness 21, while the series resonator RH4 can include a TC-SAW resonator 10 with a temperature compensation layer 16 of comparably high thickness 11. Similarly, the shunt resonator RH1 can include a TC-SAW resonator 20 with a temperature compensation layer 26 of comparably low thickness 21, while the shunt resonator RH2 can include a TC-SAW resonator 10 with a temperature compensation layer 16 of comparably high thickness 11.

Acoustic wave filters disclosed herein can be implemented in a variety of packaged modules. Some example packaged modules will now be discussed in which any suitable principles and advantages of the acoustic wave filters disclosed herein can be implemented. Example packaged modules include one or more acoustic wave filters and one or more radio frequency amplifiers (e.g., one or more power amplifiers and/or one or more low noise amplifiers) and/or one or more radio frequency switches. The example packaged modules can include a package that encloses the illustrated circuit elements. The illustrated circuit elements can be disposed on the same packaging substrate. The packaging substrate can be a laminate substrate, for example.

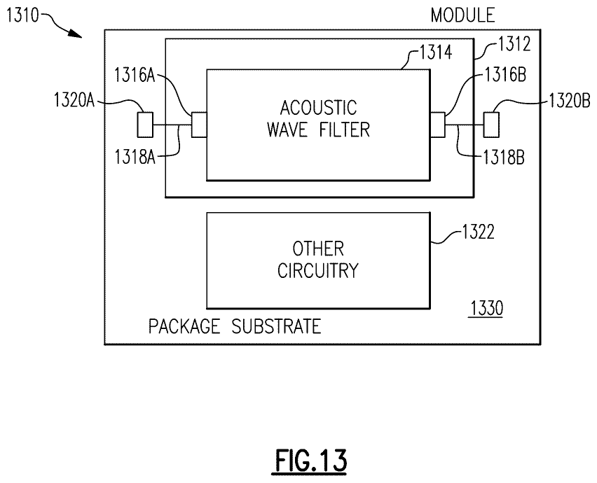

FIG. 13 is a schematic diagram of a radio frequency module 1310 that includes an acoustic wave component 1312 according to an embodiment. The illustrated radio frequency module 1310 includes the acoustic wave component 1312 and other circuitry 1322. The acoustic wave component 1312 can include one or more acoustic wave filters in accordance with any suitable combination of features disclosed herein. The acoustic wave component 1312 can include an acoustic wave die that includes acoustic wave devices.

The acoustic wave component 1312 shown in FIG. 13 includes a filter 1314 and terminals 1316A and 1316B. The filter 1314 can include band pass filters that include temperature compensated surface acoustic wave (TC-SAW) resonators having temperature compensation layers of different thickness in accordance with any suitable principles and advantages disclosed herein. The terminals 1316A and 1316B can serve, for example, as an input contact and an output contact. The acoustic wave component 1312 and the other circuitry 1322 are on the same packaging substrate 1330 in FIG. 13. The packaging substrate 1330 can be a laminate substrate. The terminals 1316A and 1316B can be electrically connected to contacts 1320A and 1320B, respectively, on the packaging substrate 1330 by way of electrical connectors 1318A and 1318B, respectively. The electrical connectors 1318A and 1318B can be bumps or wire bonds, for example.

The other circuitry 1322 can include any suitable additional circuitry. The other circuitry 1322 can include radio frequency circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, other radio frequency front end circuitry, the like, or any suitable combination thereof. The other circuitry 1322 can be electrically connected to the filter 1314. The radio frequency module 1310 can include one or more packaging structures to, for example, provide protection and/or facilitate easier handling of the radio frequency module 1310. Such a packaging structure can include an overmold structure formed over the packaging substrate 1330. The overmold structure can encapsulate some or all of the components of the radio frequency module 1310.

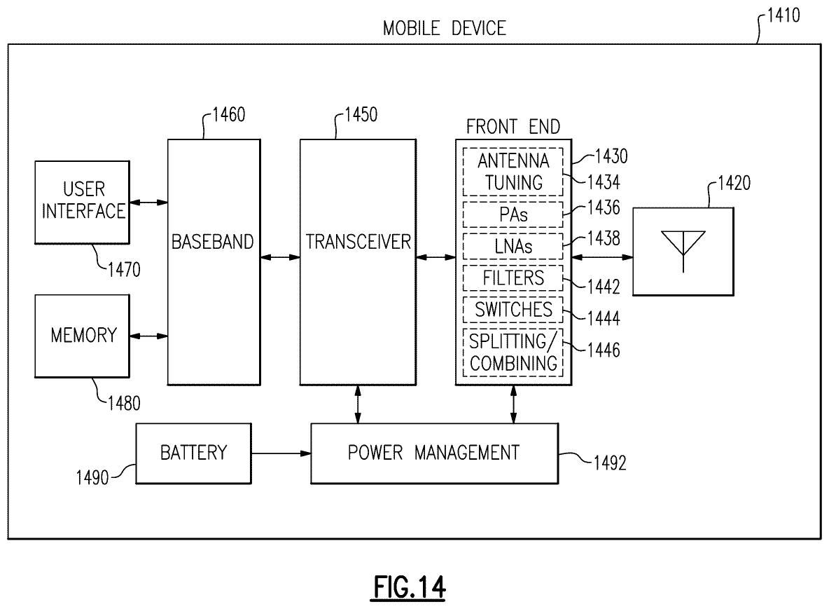

Acoustic wave filters disclosed herein can be implemented in a variety of wireless communication devices, such as mobile devices. One or more filters implemented with any suitable principles and advantages disclosed herein can be included in a variety of wireless communication devices, such as mobile phones. The acoustic wave filters can be included in a radio frequency front end. FIG. 14 is a schematic diagram of one embodiment of a mobile device 1410. The mobile device 1410 includes a baseband system 1460, a transceiver 1450, a front end system 1430, antennas 1420, a power management system 1492, a memory 1480, a user interface 1470, and a battery 1490.

The mobile device 1410 can be used communicate using a wide variety of communications technologies, including, but not limited to, second generation (2G), third generation (3G), fourth generation (4G) (including LTE, LTE-Advanced, and LTE-Advanced Pro), fifth generation (5G) New Radio (NR), wireless local area network (WLAN) (for instance, Wi-Fi), wireless personal area network (WPAN) (for instance, Bluetooth and ZigBee), WMAN (wireless metropolitan area network) (for instance, WiMax), Global Positioning System (GPS) technologies, or any suitable combination thereof.

The transceiver 1450 generates RF signals for transmission and processes incoming RF signals received from the antennas 1420. It will be understood that various functionalities associated with the transmission and receiving of RF signals can be achieved by one or more components that are collectively represented in FIG. 14 as the transceiver 1450. In one example, separate components (for instance, separate circuits or dies) can be provided for handling certain types of RF signals.

The front end system 1430 aids in conditioning signals transmitted to and/or received from the antennas 1420. In the illustrated embodiment, the front end system 1430 includes antenna tuning circuitry 1434, power amplifiers (PAS) 1436, low noise amplifiers (LNAs) 1438, filters 1442, switches 1444, and signal splitting/combining circuitry 1446. However, other implementations are possible. One or more of the filters 1442 can be implemented in accordance with any suitable principles and advantages disclosed herein. For example, one or more of the filters 1442 can include parallel acoustic wave filters in accordance with any suitable principles and advantages disclosed herein.

The front end system 1430 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or any suitable combination thereof.

In certain implementations, the mobile device 1410 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 1420 can include antennas used for a wide variety of types of communications. For example, the antennas 1420 can include antennas for transmitting and/or receiving signals associated with a wide variety of frequencies and communications standards.

In certain implementations, the antennas 1420 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate (BER) and/or a received signal strength indicator (RSSI).

The mobile device 1410 can operate with beamforming in certain implementations. For example, the front end system 1430 can include amplifiers having controllable gain and phase shifters having controllable phase to provide beam formation and directivity for transmission and/or reception of signals using the antennas 1420. For example, in the context of signal transmission, the amplitude and phases of the transmit signals provided to the antennas 1420 are controlled such that radiated signals from the antennas 1420 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 1420 from a particular direction. In certain implementations, the antennas 1420 include one or more arrays of antenna elements to enhance beamforming.

The baseband system 1460 is coupled to the user interface 1470 to facilitate processing of various user input and output (I/O), such as voice and data. The baseband system 1460 provides the transceiver 1450 with digital representations of transmit signals, which the transceiver 1450 processes to generate RF signals for transmission. The baseband system 1460 also processes digital representations of received signals provided by the transceiver 1450. As shown in FIG. 14, the baseband system 1460 is coupled to the memory 1480 to facilitate operation of the mobile device 1410.

The memory 1480 can be used for a wide variety of purposes, such as storing data and/or instructions to facilitate the operation of the mobile device 1410 and/or to provide storage of user information.

The power management system 1492 provides a number of power management functions of the mobile device 1410. In certain implementations, the power management system 1492 includes a PA supply control circuit that controls the supply voltages of the power amplifiers 1436. For example, the power management system 1492 can be configured to change the supply voltage(s) provided to one or more of the power amplifiers 1436 to improve efficiency, such as power added efficiency (PAE).

As shown in FIG. 14, the power management system 1492 receives a battery voltage from the battery 1490. The battery 1490 can be any suitable battery for use in the mobile device 1410, including, for example, a lithium-ion battery.

Technology disclosed herein can be implemented in acoustic wave filters in 5G implementations. 5G technology is also referred to herein as 5G New Radio (NR). 5G NR supports and/or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein can be applied to a standalone filter in some implementations. The teachings herein can be applied to one or more filters in a multiplexer that includes a plurality of filters coupled to each other at a common node.

The teachings herein are applicable to a wide variety of communication systems, including, but not limited to, communication systems using advanced cellular technologies, such as LTE-Advanced, LTE-Advanced Pro, and/or 5G NR. A filter including any suitable combination of features disclosed herein be arranged to filter a radio frequency signal in a 5G NR operating band within Frequency Range 1 (FR1). A filter arranged to filter a radio frequency signal in a 5G NR operating band can be implemented in accordance with any suitable principles and advantages disclosed herein. The filter can be arranged to filter signals within FR1 and having a frequency below 5 GHz. The filter can be arranged to filter signals within FR1 and having a frequency below 3.5 GHz. FR1 can be from 410 MHz to 7.125 GHz, for example, as specified in a current 5G NR specification. One or more acoustic wave filters in accordance with any suitable principles and advantages disclosed herein can filter a radio frequency signal in a fourth generation (4G) Long Term Evolution (LTE) band. An acoustic wave filter in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) implementation. Acoustic wave filters disclosed herein can advantageously implement relatively wide passbands for certain 5G implementations.

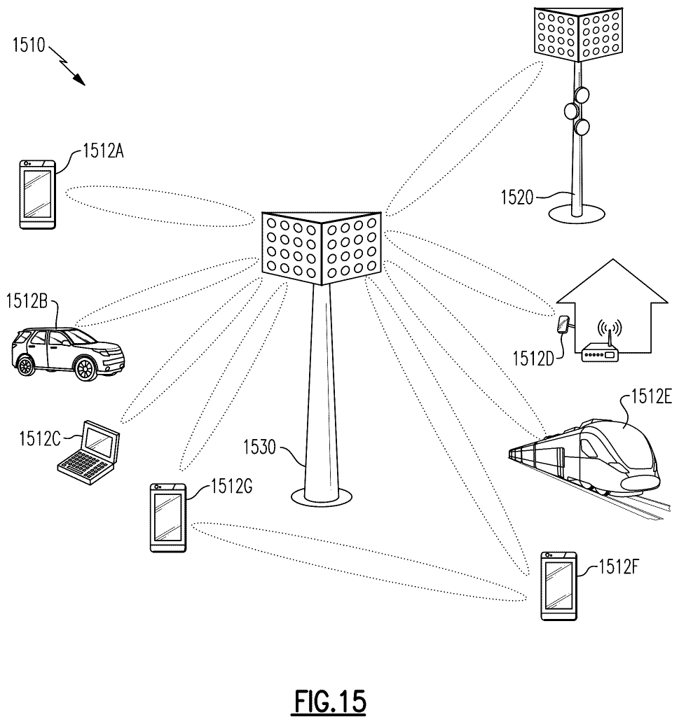

FIG. 15 is a schematic diagram of one example of a communication network 1510. The communication network 1510 includes a macro cell base station 1530, a small cell base station 1520, and various examples of user equipment (UE), including a first mobile device 1512A, a wireless-connected car 1512B, a laptop 1512C, a stationary wireless device 1512D, a wireless-connected train 1512E, a second mobile device 1512F, and a third mobile device 1512G. UEs are wireless communication devices. One or more of the macro cell base station 1530, the small cell base station 1520, or UEs illustrated in FIG. 15 can implement one or more of the acoustic wave filters in accordance with any suitable principles and advantages disclosed herein. For example, one or more of the UEs shown in FIG. 15 can include one or more acoustic wave filters in accordance with any suitable principles and advantages disclosed herein.

Although specific examples of base stations and user equipment are illustrated in FIG. 15, a communication network can include base stations and user equipment of a wide variety of types and/or numbers. For instance, in the example shown, the communication network 1510 includes the macro cell base station 1530 and the small cell base station 1520. The small cell base station 1520 can operate with relatively lower power, shorter range, and/or with fewer concurrent users relative to the macro cell base station 1530. The small cell base station 1520 can also be referred to as a femtocell, a picocell, or a microcell. Although the communication network 1510 is illustrated as including two base stations, the communication network 1510 can be implemented to include more or fewer base stations and/or base stations of other types.

Although various examples of user equipment are shown, the teachings herein are applicable to a wide variety of user equipment, including, but not limited to, mobile phones, tablets, laptops, Internet of Things (IoT) devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 1510 of FIG. 15 supports communications using a variety of cellular technologies, including, for example, 4G LTE and 5G N.R. In certain implementations, the communication network 1510 is further adapted to provide a wireless local area network (WLAN), such as Wi-Fi. Although various examples of communication technologies have been provided, the communication network 1510 can be adapted to support a wide variety of communication technologies.

Various communication links of the communication network 1510 have been depicted in FIG. 15. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and Wi-Fi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed Wi-Fi frequencies).

As shown in FIG. 15, the communication links include not only communication links between UE and base stations, but also UE to UE communications and base station to base station communications. For example, the communication network 1510 can be implemented to support self-fronthaul and/or self-backhaul (for instance, as between mobile device 1512G and mobile device 1512F).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. According to certain implementations, the communication links can serve Frequency Range 1 (FR1), Frequency Range 2 (FR2), or a combination thereof. An acoustic wave filter in accordance with any suitable principles and advantages disclosed herein can filter a radio frequency signal within FR1. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 1510 can share available network resources, such as available frequency spectrum, in a wide variety of ways. In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 3 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 1510 of FIG. 15 can be used to support a wide variety of advanced communication features, including, but not limited to, eMBB, uRLLC, and/or mMTC.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 450 MHz to 3.5 GHz, in a frequency range from about 400 MHz to 8.5 GHz, or in a frequency range from about 734 MHz to 8.5 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including,” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel filters, devices, modules, radio frequency systems, wireless communication devices, apparatus, methods, and systems described herein may be embodied in a variety of other forms. Furthermore, various omissions, substitutions and changes in the form of the filters, multiplexer, devices, modules, radio frequency systems, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. An acoustic wave filter comprising:
a first input/output port and a second input/output port;
a plurality of temperature compensated surface acoustic wave (TC-SAW) series resonators coupled in series between the first input/output port and the second input/output port, each of the plurality of TC-SAW series resonators having a layer of piezoelectric material, an interdigital transducer (IDT) electrode arranged over the layer of piezoelectric material, and a temperature compensation layer formed over the IDT electrode, the plurality of TC-SAW series resonators including at least one first TC-SAW series resonator and at least one second TC-SAW series resonator, a thickness of the temperature compensation layer of the at least one first TC-SAW series resonator being less than a thickness of the temperature compensation layer of the at least one second TC-SAW series resonator;
a plurality of TC-SAW shunt resonators coupling the plurality of TC-SAW series resonators to ground; and
an inductor connected in parallel to the at least one first TC-SAW series resonator.

2. The acoustic wave filter of claim 1 wherein the temperature compensation layers of the plurality of TC-SAW series resonators are silicon dioxide (SiO₂) layers.

3. The acoustic wave filter of claim 1 wherein the IDT electrodes of the plurality of TC-SAW series resonators include a bus bar and IDT fingers extending from the bus bar, the IDT fingers having a pitch of λ corresponding to a wavelength of a resonant frequency of the plurality of TC-SAW series resonators, the thickness of the temperature compensation layer of the at least one first TC-SAW series resonator having a value between about 0.2 λ and about 0.4 λ.

4. The acoustic wave filter of claim 3 wherein the thickness of the temperature compensation layer of the at least one second TC-SAW series resonator has a value of larger than about 0.5 λ.

5. The acoustic wave filter of claim 1 wherein the layer of piezoelectric material of the plurality of TC-SAW series resonators includes a lithium niobate crystal with a 120° to 132° rotated Y-cut, X-propagating cut angle.

6. The acoustic wave filter of claim 1 wherein the plurality of TC-SAW shunt resonators include at least one first TC-SAW shunt resonator and at least one second TC-SAW shunt resonator, a thickness of a temperature compensation layer of the at least one first TC-SAW shunt resonator being less than a thickness of a temperature compensation layer of the at least one second TC-SAW shunt resonator.

7. The acoustic wave filter of claim 1 wherein the acoustic wave filter is a band pass filter.

8. The acoustic wave filter of claim 7 wherein the first input/output port is a transmit port for a transmit filter or a receive port for a receive filter, and the second input/output port is an antenna port configured to be connected to an antenna.

9. The acoustic wave filter of claim 8 wherein the at least one first TC-SAW series resonator and the inductor connected in parallel to the at least one first TC-SAW series resonator are directly coupled to the first input/output port.

10. The acoustic wave filter of claim 8 wherein the at least one first TC-SAW series resonator and the inductor connected in parallel to the at least one first TC-SAW series resonator are directly coupled to the second input/output port.

11. A radio-frequency (RF) module comprising an acoustic wave filter including a first input/output port and a second input/output port, a plurality of temperature compensated surface acoustic wave (TC-SAW) series resonators coupled in series between the first input/output port and the second input/output port, each of the plurality of TC-SAW series resonators having a layer of piezoelectric material, an interdigital transducer (IDT) electrode arranged over the layer of piezoelectric material, and a temperature compensation layer formed over the IDT electrode, the plurality of TC-SAW series resonators including at least one first TC-SAW series resonator and at least one second TC-SAW series resonator, a thickness of the temperature compensation layer of the at least one first TC-SAW series resonator being less than a thickness of the temperature compensation layer of the at least one second TC-SAW series resonator, a plurality of TC-SAW shunt resonators coupling the plurality of TC-SAW series resonators to ground, and an inductor connected in parallel to the at least one first TC-SAW series resonator, an RF antenna coupled to the second input/output port, and a power amplifier coupled to the first input/output port and configured to amplify an RF signal for transmission or received by the RF antenna.

12. The RF module of claim 11 wherein the IDT electrodes of the plurality of TC-SAW series resonators include a bus bar and IDT fingers extending from the bus bar, the IDT fingers having a pitch of λ corresponding to a wavelength of a resonant frequency of the plurality of TC-SAW series resonators, the thickness of the temperature compensation layer of the at least one first TC-SAW series resonator having a value between about 0.2 λ and about 0.4 λ.

13. The RF module of claim 12 wherein the thickness of the temperature compensation layer of the at least one second TC-SAW series resonator has a value of larger than about 0.5 λ.

14. The RF module of claim 11 wherein the acoustic wave filter is a ladder-type acoustic wave filter.

15. The RF module of claim 11 wherein the acoustic wave filter is a lattice-type or a hybrid ladder-lattice-type acoustic wave filter.

16. The RF module of claim 11 wherein the layer of piezoelectric material of the plurality of TC-SAW series resonators includes a lithium niobate crystal with a 120° to 132° rotated Y-cut, X-propagating cut angle.

17. The RF module of claim 11 wherein the plurality of TC-SAW shunt resonators include at least one first TC-SAW shunt resonator and at least one second TC-SAW shunt resonator, a thickness of a temperature compensation layer of the at least one first TC-SAW shunt resonator being less than a thickness of a temperature compensation layer of the at least one second TC-SAW shunt resonator.

18. The RF module of claim 11 wherein the acoustic wave filter is a transmit filter or a receive filter, and the second input/output port is an antenna port connected to the RF antenna.

19. The RF module of claim 18 wherein the at least one first TC-SAW series resonator and the inductor connected in parallel to the at least one first TC-SAW series resonator are directly coupled to the first input/output port, and the at least one first TC-SAW series resonator and the inductor connected in parallel to the at least one first TC-SAW series resonator are directly coupled to the second input/output port.

20. A multiplexer comprising:
a first input/output port, a second input/output port, and a third input/output port;
a first plurality of temperature compensated surface acoustic wave (TC-SAW) series resonators coupled in series between the first input/output port and the second input/output port, each of the first plurality of TC-SAW resonators having a layer of piezoelectric material, an interdigital transducer (IDT) electrode arranged over the layer of piezoelectric material, and a temperature compensation layer formed over the IDT electrode, the first plurality of TC-SAW series resonators including at least one first TC-SAW series resonator and at least one second TC-SAW series resonator, a thickness of the temperature compensation layer of the at least one first TC-SAW series resonator being less than a thickness of the temperature compensation layer of the at least one second TC-SAW series resonator;
a second plurality of TC-SAW series resonators, each having a layer of piezoelectric material, an IDT electrode arranged over the layer of piezoelectric material, and a temperature compensation layer formed over the IDT electrode coupled in series between the second input/output port and the third input/output port, the second plurality of TC-SAW series resonators including at least one third TC-SAW series resonator and at least one fourth TC-SAW series resonator, a thickness of the temperature compensation layer of the at least one third TC-SAW series resonator being less than a thickness of the temperature compensation layer of the at least one fourth TC-SAW series resonator;
a plurality of TC-SAW shunt resonators coupling the first plurality of TC-SAW series resonators and the second plurality of TC-SAW series resonators to ground;
a first inductor connected in parallel to the at least one first TC-SAW series resonator; and
a second inductor connected in parallel to the at least one third TC-SAW series resonator.
